(19) United States
(12) Patent Application Publication
(10) Pub. No.: US 2005/0083108 A1
(43) Pub. Date: Apr. 21, 2005

(54) Analog multiplexers with CMOS control signals

(76) Inventor: Sami Kiriaki, Plano, TX (US)

Correspondence Address: TEXAS INSTRUMENTS INCORPORATED, P O BOX 655474, M/S 3999, DALLAS, TX, 75265, US

(21) Appl. No.: 10/983,475

(22) Filed: Nov. 8, 2004

Related U.S. Application Data
(62) Division of application No. 09/711,714, filed on Nov. 13, 2000.

(51) Int. Cl. H03K 19/177

(52) U.S. Cl. 327/408

(57) ABSTRACT

Analog multiplexer circuits with CMOS control signals and with low signal feed-through and high bandwidth are described. These circuits emphasize low parasitic capacitance through circuit layout techniques and the use of smaller size n-channel transistors where possible. These circuits can be used for both single-ended and differential configurations. Two embodiments of the circuit are discussed allowing for optimal selection of multiplexers in application requirements ranging from lower-to-higher bandwidth and small-to-large input signal size.

### BACKGROUND OF THE INVENTION

1. Field of the Invention

This invention relates to fast analog multiplexers with CMOS control signals and particularly to the elimination of cross-signal feed-through in these high speed circuits.

2. Brief Description of the Known Art

FIG. 1a shows the simplest type of conventional analog multiplexer 1 (MUX) built with CMOS switches. Here, the MUX switches are comprised of n-channel MOS transistors 2-4 and p-channel MOS transistors 5-7, connected in parallel to form a CMOS switch. This shows a n-to-1 MUX with input signals sig₁, sig₂, . . . sig n connected to MUX switches 2/5, 3/6, and 4/7, respectively. The output of the MUX switches are connected together and become the output of the MUX circuit. The MUX switches are controlled by placing complementary control voltages on the transistor gates, as shown. The logic circuit for generating these control signals is comprised of two inverters 8 and 9, as shown in FIG. 1b. As example, for operation between 0 volts and positive power supply VDD, the switches are turned “ON” and “OFF” at their gates, as follows:

| | n-Channel | p-Channel |
|---|---|---|
| | Transistor | Transistor |
| ON | V_{DD} | 0 V |
| OFF | 0 V | V_{DD} |

where V_{DD} is the positive power supply (e.g. +5V) and 0V is ground.
   By having the n-channel and p-channel transistors connected in parallel, the circuit can handle signals from 0 to V_{DD} volts, as illustrated in FIG. 1c. In this figure, V_{sig} is plotted on the abscissa and the ON resistance of the switches, R_{SW}, is plotted on the ordinate. The transistors tend to be “ON” over the following voltage ranges, respectively:
n-channel: 0→[V_{DD}−Vₜₕ_{_{(n-ch)}}]
p-channel V_{DD}→[0+Vₜₕ_{_{(p-ch)}}]
   This means that for small signals the n-channel transistor is primarily used and for large signals the p-channel transistor is primarily used. Also, the ON resistance, R_{SW}, tends to be optimal (lowest) in mid-signal range where both parallel transistors are ON.

The primary problem with analog multiplexers of this type, used to select one of several input signals, is that they often have undesirable signal feed-through where an attenuated level of an unselected signal appears as part of the output signal. This feed-through is due primarily to the parasitic capacitances, C_{gd} and C_{gs}, associated with the CMOS transistors used to implement the switches. As a result, this undesirable feed-through causes a degradation at the output of both the signal-to-noise ratio (SNR) and the signal-to-distortion ratio (SDR) for the selected signal at the output of the MUX.

Thus, there is a need for an improved high speed MUX which eliminates the cross-signal feed-through problems of the prior art. The invention and embodiment disclosed herein address this need.

For reference, U.S. Pat. Nos. 5,744,995 discusses multi-input multiplexers and U.S. Pat. No. 5,598,114 discusses high-speed multiplexers.

### SUMMARY OF THE INVENTION

This invention addresses the shortcomings of prior art analog multiplexers, depending on the application, to provide low-distortion, high-speed solutions. The objective is to provide high-speed multiplexers which eliminates cross-signal feed-through at the circuit's output. These designs take into account such parameters as input signal level, signal bandwidth, common mode operation, parasitic capacitance, and transistor layout.

The circuits of this invention use N-MOS/P-MOS transistor pairs for signal switches and additional N_MOS transistors to effectively shunt the unselected signal paths to circuit ground, thereby considerably reducing the amount of undesired signal presence at the circuit's output.

Two embodiments of the invention address the signal feed-through issue with CMOS circuitry; one for limited bandwidth applications and one for small signal applications. For small signal applications, the P-MOS transistors in the signal switches of these circuits are eliminated, leaving only the N-MOS transistors, to provide improved bandwidth and lower signal feed-through. All of the techniques of this invention can be applied to both single-ended and/or differential configurations.

Also, the layout of CMOS transistors with reduced parasitic capacitance, used in the implementation of the circuits of this invention, are included in the discussion.

### BRIEF DISCRIPTION OF THE DRAWINGS

The included drawings are as follows:

FIG. 1a shows a schematic for a simple analog MUX with CMOS control. (prior art)

FIG. 1b shows a typical schematic of the control logic for an analog MUX. (prior art)

FIG. 1c illustrates the switching characteristics for the n-channel and p-channel transistors commonly used in the analog MUX circuitry. (prior art)

FIG. 2 shows the schematic for a CMOS MUX of this invention with improved input signal feed-through.

FIG. 3 shows the schematic for a small-signal, high-bandwidth, single-ended CMOS MUX of this invention with improved input signal feed-through.

FIG. 4 shows the schematic for a small-signal, high-bandwidth, differential CMOS MUX of this invention with improved input signal feed-through.

FIGS. 5a and 5b illustrate the layout of the CMOS transistors of this invention with reduced parasitic output capacitance for use in analog multiplexer applications.

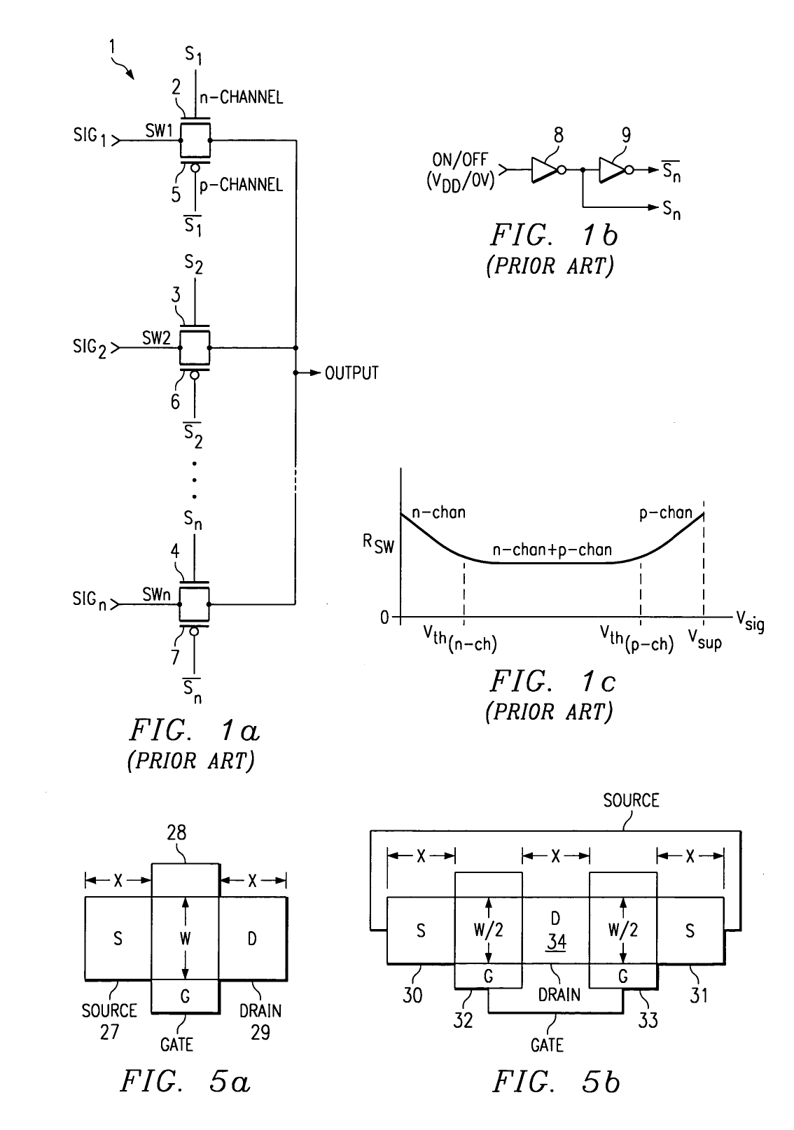

### DESCRIPTION OF THE PREFERRED EMBODIMENT

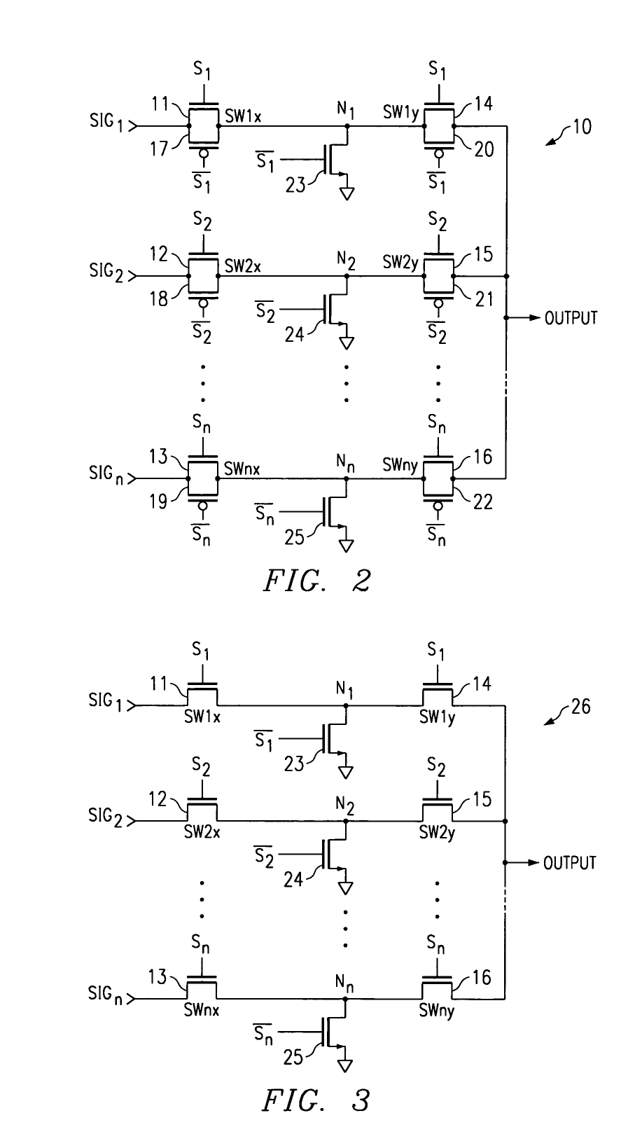

FIG. 2 shows one embodiment for a CMOS MUX 10 with improved signal feed-through characteristics. The circuit is comprised of an input pair of n-channel 11-13/p-channel 17-19 MOS transistor switches and an output pair of n-channel 14-16/p-channel 20-22 MOS transistor switches connected in series at each input and additional n-channel MOS transistors 23-25 connected, as pull-down devices, between each series transistor pair and circuit ground. Input signals Sig₁, Sig₂, and Sigₙ are connected to transistors pairs 11/17, 12/18, and 13/19, respectively. The outputs of MOS transistor pairs 14/20, 15/21, and 16/22 are tied together to form a low feed-through output signal. Each of the series n-channel MOS transistors 11-16 are driven at the gate by logic control signals, Sₙ, while the series p-channel MOS transistors 17-22 and n-channel MOS pull-down transistors 23-25 are driven by logic control signals, \overline{Sₙ}, which are complementary to the above 11-16. As a result, the overall effect of this circuit arrangement is as though there were individual switches, with low signal feed-through, for each input signal.

In operation, when one signal is selected, all other signals are shunted to ground by their associated pull-down transistors, such that feed-through from the unselected signals is eliminated at the output. For example, if Sig₂ is selected, then MOS pull-down transistor switch 24 is OFF, allowing the Sig₂ signal to pass through to the output while MOS pull-down transistors 23 and 25 are ON, shunting any feed-through from signals Sig₁ and Sigₙ to ground and preventing any feed-through of these unselected signals at the output. Either the n-channel or p-channel MOS transistor can be selected as the ON switch, depending on the level of the input signal.

This circuit is limited to rather low bandwidth applications due to the total RC time constant associated with each switch. For example, switch SW1x 11/17 has an ON resistance of R_{1X} and a total parasitic capacitance C_{1X} at node N₁ and switch SW1y 14/20 has an ON resistance of R_{1Y} and a total parasitic capacitance C_{1Y} at the output node. Therefore, the total RC time constant for Sig₁ is given as:
R_{1X}·C_{1X}+R_{1Y}·C_{1Y}
For a given switch control level and common mode signal, the switch ON resistance can be reduced by increasing the widths of both the N-MOS and P-MOS transistors. However, this reduction in ON resistance is typically accompanied by an increase in the drain-to-bulk and source-to-bulk parasitic capacitance. But, an optimum design can be found for a limited number of signals that are joined together at the MUX output for a given application.

In a second embodiment of the circuit 26, for the case of small signal applications where the input signal is a small fraction of the MUX supply voltage, the switch bandwidth can be improved by modifying the circuit as shown in FIG. 3. Since the mobility of electrons is approximately three times greater than that for holes, the problem with the ON switch resistance discussed above is magnified by the fact that P-MOS device sizes must be made three times or more the size of the N-MOS devices to overcome this mobility difference. However, this larger size for the P-MOS devices results in larger parasitic capacitance which in turn increases the RC time constant and reduces the switch bandwidth. In this circuit, used primarily for small signal applications, the p-channel MOS transistors 17-22 (in FIG. 2) are eliminated completely so that the series switches consists of only n-channel MOS transistor switches 11-16 and the n-channel MOS shunting transistors 23-25. Otherwise, the circuit configuration is the same as in FIG. 2. In this circuit the parasitic capacitance is reduced by as much as 50%, assuming the signal common mode level is closer to the MUX ground and the peak-to-peak signal level is a small fraction of the MUX supply voltage. This configuration is applicable as long as the signal voltage level (V_{cm}+V_{sig}) produces enough V_{gs} for the series N-MOS transistors 11-16 to maintain a low ON resistance.

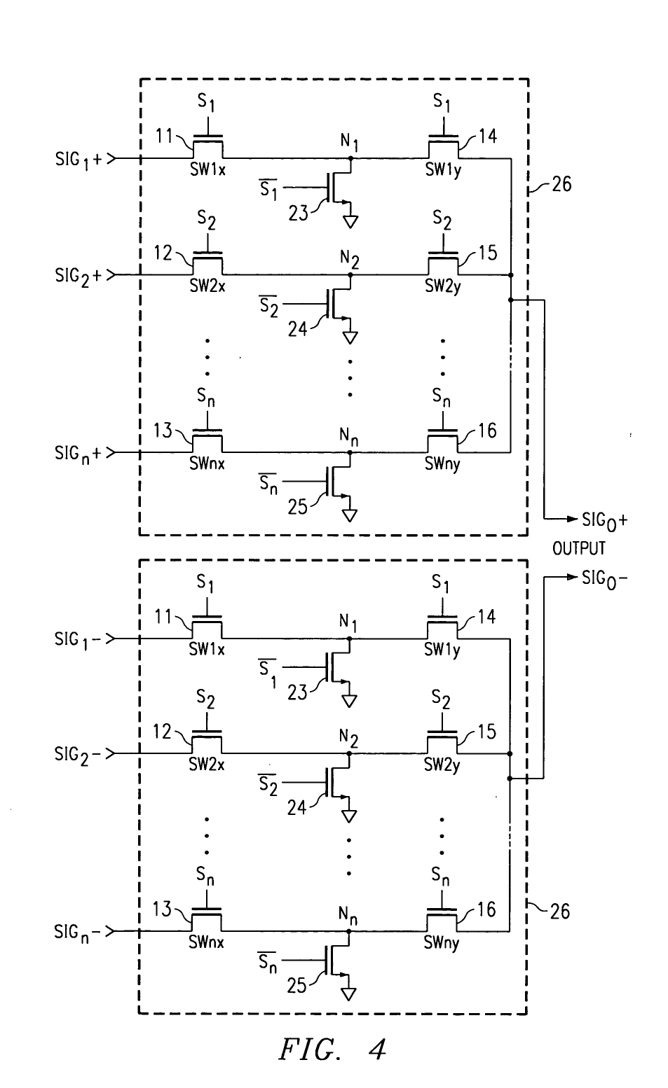

The circuits discussed above are shown for single-ended signal applications. However, all these circuits can be implemented for fully differential operation, as illustrated in FIG. 4 for the small signal circuit discussed above. This circuit is essentially comprised of two of the single-ended circuits 26 coupled so as to provide for differential inputs signals Sig₁+/Sig₁−, Sig₂+/Sig₂−, Sigₙ+/Sigₙ− and a differential output signal Sig₀+/Sig₀−.

The parasitic capacitance in these high-speed MUX circuits can be further reduced by using an even number of “fingers” in the circuit layout of the series output transistors SW1y 14, SW2y 15, SWny 16, as illustrated in FIGS. 5a and 5b. FIG. 5a shows a typical layout for a single finger N-MOS transistor which is comprised of a source 27, a gate 28, and a drain 29. In this case the source and drain capacitances are equal and given as the area of the gate width (w) and drain/source length (x), as follows:
C_{S}=C_{D}=x·w
On the other hand, for the lower capacitance layout of this invention, shown in FIG. 5b, the gate and source are split into two parts, or “fingers”, so that the transistor is comprised of sources 30 and 31, gates 32 and 33, and drain 34, and the capacitance-to-area relationship becomes:

$$\begin{matrix}{C}_{D} = x \cdot \frac{w}{2} , and \\ {C}_{S} = 2 \cdot x \cdot \frac{w}{2} = x \cdot w , so that \\ {C}_{S} = 2 \cdot {C}_{D} .\end{matrix}$$

This means that a two “finger” device has a drain-to-bulk parasitic capacitance, C_{dB}, that is one-half the source capacitance, C_{S}, and as a result the total output capacitance is reduced by at least 50%. This layout can be used to obtain a significant boost, where the bandwidth of the MUX circuit is at least doubled.

While the invention has been described in the context of two preferred embodiments, it will appear to those skilled in the art that the present invention may be modified in numerous ways and may assume many embodiments other than that specifically set out and described above. Accordingly, it is intended by the appended claims to cover all modifications of the invention which fall within the true spirit and scope of the invention.

1-4. (canceled)

5. A CMOS analog multiplexer circuit comprising:
multiple series n-channel MOS transistor input switches;
multiple series n-channel MOS transistor output switches;
multiple n-channel MOS transistor pull-down switches; wherein
said circuit is capable of multiplexing small level analog signals having amplitudes which are a small fraction of the power source;
said circuit's parasitic capacitance is reduced by as much as 50%;
said circuit's bandwidth is at least doubled; and
said circuit prevents cross-signal feed-through from unselected inputs by shunting said feed-through to circuit ground.

6. The CMOS analog multiplexer circuit of claim 5 further comprising:
the input of a first series input n-channel MOS transistor switch coupled to the first circuit input signal;
the input of a second series input n-channel MOS transistor switch coupled to the second circuit input signal;
the input of a nth series input n-channel MOS transistor switch coupled to the nth circuit input signal;
the output of said first series input n-channel MOS transistor switch coupled to the input of a first output n-channel transistor switch and to the drain of a first n-channel MOS pull-down transistor;
the output of said second series input n-channel MOS transistor switch coupled to the input of a second output n-channel MOS transistor switch and to the drain of a second n-channel MOS pull-down transistor;
the output of said nth series input n-channel MOS transistor switch coupled to the input of a nth output n-channel MOS transistor switch and to the drain of a nth n-channel MOS pull-down transistor;
the outputs of said first, second, and nth output n-channel MOS transistor switches coupled together and to the circuit output;
the sources of said first, second, and nth n-channel MOS pull-down transistors coupled to circuit ground;
the gates of all said series input and output n-channel MOS transistor switches coupled to a logic control signal;
the gates of all said n-channel MOS pull-down transistors coupled to a logic control signal which is the complement of said series input/output transistor logic control signal.

7. A CMOS analog multiplexer circuit for use with differential input signals, comprising:
multiple positive and negative signal series n-channel MOS transistor input switches;
multiple positive and negative signal series n-channel MOS transistor output switches;
multiple positive and negative signal n-channel MOS transistor pull-sown switches; wherein
said series positive and negative MOS transistor switch's capacitacne is reduced by at least 50% by means of eliminating the p-channel MOS transistors;
said circuit's bandwidth is at least doubled by means of eliminating said p-channel MOS transistors;
said circuit is capable of multiplexing small level analog signals having amplitudes which are a small fraction of the power source; and
said circuit prevents cross-signal feed-through from unselected inputs by shunting said feed-through to circuit ground.

8. The CMOS analog multiplexer circuit of claim 7 further comprising:
the positive inputs of multiple differential input signals coupled to corresponding multiple positive input series n-channel MOS transistor switches, respectively;
the outputs of said multiple positive input series input n-channel MOS transistor switches coupled to the inputs of multiple positive output n-channel MOS transistor switches, respectively, and to the drains of multiple positive n-channel MOS pull-down transistors;
the outputs of said multiple positive output n-channel MOS transistor switches coupled together and connected to the positive differential circuit output;
the sources of said multiple positive n-channel MOS pull-down transistors coupled to circuit ground;
the gates of all said positive series input and output n-channel MOS transistor switches coupled to a logic control signal;
the gates of all said positive n-channel MOS pull-down transistors coupled to a logic control signal that is complementary to said positive series input/output logic control signal;
the negative inputs of multiple differential input signals coupled to corresponding multiple negative input series n-channel MOS transistor switches, respectively;
the outputs of said multiple negative input series input n-channel MOS transistor switches coupled to the inputs of multiple negative output n-channel MOS transistor switches, respectively, and to the drains of multiple negative n-channel MOS pull-down transistors;
the outputs of said multiple negative output n-channel MOS transistor switches coupled together and connected to the negative differential circuit output;
the sources of said multiple negative n-channel MOS pull-down transistors coupled to circuit ground;
the gates of all said negative series input and output n-channel MOS transistor switches coupled to a logic control signal;
the gates of all said negative n-channel MOS pull-down transistors coupled to a logic control signal that is complementary to said negative series input/output logic control signal.

9. The CMOS analog multiplexer circuit of claim 6 or 8 further comprising MOS transistor layouts having an even number of circuit fingers: wherein said MOS transistor's parasitic capacitance is further reduced by more than 50%; and said MOS transistor's bandwidth is further improved by at least two times.

10. The CMOS transistor layout of claim 9 further comprising:
a CMOS transistor whose architecture has the source and gate split in half such that it consists of the sequence: one-half source, one-half gate, drain, one-half gate, and one-half source;
said CMOS transistor whose drain capacitance is half that of a conventional CMOS transistor;
said CMOS transistor whose gate is split into two parts each having a width of w/2;
said CMOS transistor whose source is split into two parts each having a width of w/2;
said two gate parts coupled together and to transistor gate output;
said two source parts coupled together and to transistor source output.
